(19) United States
(12) Patent Application Publication
(10) Pub. No.: US 2026/0302017 A1
(43) Pub. Date: Oct. 1, 2026

(54) MAGNETIC PASTE, CIRCUIT MEMBER, AND METHOD FOR MANUFACTURING CIRCUIT MEMBER

(71) Applicant: Resonac Corporation, Tokyo (JP)

(72) Inventors: Motoki YONEKURA, Tokyo (JP); Motohiro ARIFUKU, Tokyo (JP); Kosuke URASHIMA, Tokyo (JP); Hiroaki NEMOTO, Tokyo (JP)

(21) Appl. No.: 19/479,249

(22) PCT Filed: Apr. 10, 2024
(86) PCT No.: PCT/JP2024/014584

§ 371 Date: Oct. 27, 2025

(30) Foreign Application Priority Data
May 26, 2023 (JP) 2023-086806

(51) Int. Cl. H01F 1/22; H05K 1/02

(52) U.S. Cl. CPC H01F 1/22; H05K 1/0213

(57) ABSTRACT

A magnetic paste includes a magnetic powder, a thermosetting component, and a coupling agent, in which a 10% cumulative particle size on a volume basis of the magnetic powder is 0.6 to 2.0 μm, a 50% cumulative particle size on a volume basis of the magnetic powder is 1.1 to 3.6 μm, and a 90% cumulative particle size on a volume basis of the magnetic powder is 2.1 to 6.3 μm.

### TECHNICAL FIELD

The present disclosure relates to a magnetic paste, a circuit member, and a method for manufacturing a circuit member.

### BACKGROUND ART

Materials containing metal powders having various physical properties are used according to the characteristics required for industrial products. For example, in fields such as inductors, electromagnetic wave shields, and bonded magnets, magnetic materials containing magnetic powder are used. Among them, in recent years, demand for materials containing magnetic powder and resin has been increasing (see, for example, Patent Literature 1).

### CITATION LIST

### Patent Literature

Patent Literature 1: Japanese Unexamined Patent Publication No. 2014-127624

### SUMMARY OF INVENTION

### Technical Problem

As a method for manufacturing a circuit member, a method of embedding a paste-like magnetic material (magnetic paste) into recesses such as through-holes, blind holes, cavities, and trenches provided in a substrate has been studied. However, with the further miniaturization of circuit members, the size of the recesses to which the magnetic paste is applied has also become smaller, and it has become difficult to sufficiently embed the magnetic paste into the recesses.

Accordingly, an object of one aspect of the present disclosure is to provide a magnetic paste that has excellent fillability for recesses (for example, through-holes, blind holes, cavities, trenches). Another object of some other aspects of the present disclosure is to provide a circuit member obtained using the magnetic paste of the above aspect and a method for manufacturing the same.

### Solution to Problem

The present disclosure provides the following [1] to in some aspects.
[1]

A magnetic paste including: a magnetic powder; a thermosetting component; and a coupling agent, wherein:
a 10% cumulative particle size on a volume basis of the magnetic powder is 0.6 to 2.0 μm;
a 50% cumulative particle size on a volume basis of the magnetic powder is 1.1 to 3.6 μm; and
a 90% cumulative particle size on a volume basis of the magnetic powder is 2.1 to 6.3 μm.
[2]

The magnetic paste according to [1], wherein a content of the magnetic powder is 70% by mass or more, based on a total mass of non-volatile content in the magnetic paste.
[3]

The magnetic paste according to [1] or [2], wherein the thermosetting component includes an epoxy group-containing compound and a curing agent.
[4]

The magnetic paste according to [3], wherein the epoxy group-containing compound includes an epoxy group-containing compound that is liquid at 25° C.
[5]

The magnetic paste according to [3] or [4], wherein the curing agent includes at least one selected from the group consisting of an amine-based curing agent and an imidazole-based curing agent.
[6]

The magnetic paste according to any one of [3] to [5], wherein the curing agent includes a curing agent that is liquid at 25° C.
[7]

The magnetic paste according to any one of [1] to [6], wherein a viscosity at 25° C. is 1 to 600 Pa·s.
[8]

The magnetic paste according to any one of [1] to [7], for filling a recess provided in a substrate for a circuit member.
[9]

A circuit member including: a substrate; and a magnetic body that fills a recess provided in the substrate,
wherein the magnetic body includes a cured product of the magnetic paste according to any one of [1] to [8].

A method for manufacturing a circuit member, including:
a step of filling a recess provided in a substrate with the magnetic paste according to any one of [1] to [8]; and
a step of curing the magnetic paste by heating.

### Advantageous Effects of Invention

According to one aspect of the present disclosure, it is possible to provide a magnetic paste that has excellent fillability for recesses. According to some other aspects of the present disclosure, it is possible to provide a circuit member obtained using the magnetic paste of the above aspect and a method for manufacturing the same.

### BRIEF DESCRIPTION OF DRAWINGS

FIG. 1 is a schematic cross-sectional view showing an example of a method for manufacturing a circuit member according to one embodiment of the present disclosure.

### DESCRIPTION OF EMBODIMENTS

In the present specification, a numerical range indicated using “to” indicates a range including the numerical values described before and after “to” as the minimum and maximum values, respectively. Unless otherwise explicitly specified, the units of the numerical values described before and after “to” are the same. In a numerical range described in stages in the present specification, the upper limit value or the lower limit value of the numerical range of one stage may be replaced with the upper limit value or the lower limit value of the numerical range of another stage. Further, in a numerical range described in the present specification, the upper limit value or the lower limit value of the numerical range may be replaced with a value shown in the Examples. Further, individually described upper limit values and lower limit values can be arbitrarily combined. “A or B” means that either A or B may be included, and both may be included. Unless otherwise specified, the materials exemplified below may be used alone or in combination of two or more. The content of each component in the paste means the total amount of a plurality of substances corresponding to each component present in the paste, unless otherwise specified.

Hereinafter, preferred embodiments of the present disclosure will be described. However, the present disclosure is not limited to the following embodiments in any way.

### [Magnetic Paste]

One embodiment of the present disclosure is a magnetic paste including: a magnetic powder; a thermosetting component; and a coupling agent, wherein a 10% cumulative particle size on a volume basis (hereinafter referred to as “D₁₀”) of the magnetic powder is 0.6 to 2.0 μm, a 50% cumulative particle size on a volume basis (hereinafter referred to as “D₅₀”) of the magnetic powder is 1.1 to 3.6 μm, and a 90% cumulative particle size on a volume basis (hereinafter referred to as “D₉₀”) of the magnetic powder is 2.1 to 6.3 μm.

Here, D₁₀ means the particle size at which the cumulative volume from the smaller particle size side reaches 10% of the total volume of the magnetic powder in the volume-based particle size distribution of the magnetic powder. D₅₀ means the particle size at which the cumulative volume from the smaller particle size side reaches 50% of the total volume of the magnetic powder in the volume-based particle size distribution of the magnetic powder. D₉₀ means the particle size at which the cumulative volume from the smaller particle size side reaches 90% of the total volume of the magnetic powder in the volume-based particle size distribution of the magnetic powder. The particle size distribution used for calculating D₁₀, D₅₀, and D₉₀ of the magnetic powder can be obtained by measuring the particle size distribution under the conditions described in the Examples using a laser diffraction/scattering particle size distribution analyzer.

The above-mentioned magnetic paste has excellent fillability for recesses such as through-holes, blind holes, cavities, and trenches (hereinafter also simply referred to as “fillability”). That is, according to the above-mentioned magnetic paste, recesses provided in a substrate for a circuit member can be favorably filled. Therefore, the above-mentioned magnetic paste is suitably used for filling recesses provided in a substrate for a circuit member. It is presumed that this effect is due to factors such as the particle size of the magnetic powder (especially D90) being sufficiently small to be able to enter recesses such as through-holes, and the particle size of the magnetic powder (especially D10) being sufficiently large so that the viscosity of the magnetic paste does not become too high.

### (Magnetic Powder)

The magnetic powder is an aggregate of magnetic particles. The magnetic particles contain at least a magnetic component. The magnetic particles may contain one type of magnetic component alone, or may contain a plurality of types of magnetic components. The magnetic particles may consist only of the magnetic component, but may further contain components other than the magnetic component. The content of the magnetic component based on the total mass of the magnetic particles may be 20% by mass or more, and the content of the magnetic component based on the total mass of the magnetic powder may be 50% by mass or more.

The magnetic component contains, for example, a metal element. The metal element contained in the magnetic component may be at least one selected from the group consisting of base metal elements, noble metal elements, transition metal elements, and rare earth elements. The metal element may be at least one selected from the group consisting of iron (Fe), copper (Cu), titanium (Ti), manganese (Mn), cobalt (Co), nickel (Ni), zinc (Zn), niobium (Nb), aluminum (Al), tin (Sn), chromium (Cr), barium (Ba), strontium (Sr), lead (Pb), silver (Ag), praseodymium (Pr), neodymium (Nd), samarium (Sm), and dysprosium (Dy).

The magnetic component may be a simple metal consisting of only one type of metal element, or may be an alloy composed of two or more types of metal elements. The alloy may include at least one selected from the group consisting of a solid solution, a eutectic, and an intermetallic compound. The alloy may be, for example, an iron alloy such as an Fe—Cr-based alloy and an Fe—Ni—Cr-based alloy. It may also be a copper alloy such as a Cu—Sn-based alloy, a Cu—Sn—P-based alloy, a Cu—Ni-based alloy, and a Cu—Be-based alloy.

The magnetic component may be a metal compound containing the above-mentioned metal element and an element other than the above-mentioned metal element. Examples of the element other than the above-mentioned metal element include at least one selected from the group consisting of carbon (C), oxygen (O), beryllium (Be), phosphorus (P), boron (B), and silicon (Si). The metal compound may be, for example, a metal oxide such as iron oxide. The metal compound may be a sintered body whose main component is a metal oxide (for example, a sintered body obtained by mixing and sintering a metal oxide and a metal element such as cobalt, nickel, and manganese).

The magnetic component may be a soft magnetic component (for example, a soft magnetic alloy) or a ferromagnetic component (for example, a ferromagnetic alloy). The magnetic component may be at least one selected from the group consisting of an Fe—Si-based alloy, an Fe—Si—Al-based alloy (Sendust), an Fe—Ni-based alloy (Permalloy), an Fe—Cu—Ni-based alloy (Permalloy), an Fe—Co-based alloy (Permendur), an Fe—Cr—Si-based alloy (electromagnetic stainless steel), an Nd—Fe—B-based alloy (rare earth magnet), an Sm—Fe—N-based alloy (rare earth magnet), an Al—Ni—Co-based alloy (Alnico magnet), and ferrite. The ferrite may be, for example, a spinel ferrite, a hexagonal ferrite, or a garnet ferrite.

From the viewpoint of obtaining higher magnetic permeability, the magnetic powder may contain at least one selected from the group consisting of Fe simple substance and Fe-based alloys. The Fe-based alloy may be at least one selected from the group consisting of an Fe—Si-based alloy, an Fe—Si—Al-based alloy, an Fe—Ni-based alloy, an Fe—Cu—Ni-based alloy, an Fe—Co-based alloy, an Fe—Cr—Si-based alloy, an Fe—Si—B-based alloy, and an Fe—Si—B—P—Nb—Cr-based alloy. From the viewpoint of obtaining even higher magnetic permeability, the magnetic powder may contain Fe amorphous alloy powder.

Fe amorphous alloy is an amorphous powder obtained by rapidly cooling an alloy, which is obtained by melting Fe as a main component together with other elements such as Si at a high temperature, and is also known as a metallic glass. The Fe amorphous alloy powder can be manufactured according to methods well known in the art. The Fe amorphous alloy powder can also be obtained as a commercially available product. Examples include product name AW2-08 and KUAMET-6B2 manufactured by Epson Atmix Corporation; product names DAPMS3, DAPMS7, DAPMSA10, DAPPB, DAPPC, DAPMKV49, DAP410L, DAP430L, and DAPHYB series manufactured by Daido Steel Co., Ltd.; and product names MH45D, MH28D, MH25D, and MH20D manufactured by Kobe Steel, Ltd. One of these Fe amorphous alloy powders may be used, or two or more may be used in combination.

All or part of the surface of the magnetic powder may be coated with a surface treatment agent. The surface treatment agent may be, for example, an inorganic surface treatment agent such as an inorganic oxide, a phosphoric acid-based compound and a phosphate-based compound, and a silane coupling agent; an organic surface treatment agent such as montan wax; or a cured resin product. A coupling agent described later can also be used as the surface treatment agent.

The magnetic powder (for example, magnetic powder including an Fe-based alloy) may have all or part of its surface coated with an insulating material. That is, the magnetic powder may include magnetic particles whose surfaces are coated with an insulating material (hereinafter, “insulation-coated magnetic particles”). Examples of the insulating material include silica, titania, calcium phosphate, montan wax, and an epoxy resin cured product. The insulation-coated magnetic particle may be an Fe amorphous alloy powder having an insulating coating. The thickness of the inorganic oxide film constituting the insulating coating may be, for example, 1 to 100 nm.

As the insulation-coated magnetic particles, for example, “KUAMET9A4” (Fe—Si—B-based alloy, D50: 20 μm, with insulating coating) manufactured by Epson Atmix Corporation, and “SAP-2C” (Fe—Si—B—P—Nb—Cr-based alloy, D50: 2.2 μm, with insulating coating) manufactured by Sintokogio, Ltd. can be used. These insulation-coated magnetic particles may be used in combination with magnetic particles without an insulating coating, and may be used in combination with, for example, soft ferrite powder “BSN-125” (Ni—Zn-based alloy, D50: 10 μm, without insulating coating) manufactured by Toda Kogyo Corp.

The shape of the magnetic particles is not particularly limited. The magnetic particles may be, for example, spherical, spheroidal, flattened, plate-like, rod-like, or needle-like. From the viewpoint of further improving the fillability of the recess, the shape of the magnetic particles may be spherical. Here, that the magnetic particles are spherical means that the average value of the aspect ratio, which is the ratio of the major axis to the minor axis (major axis/minor axis) of the magnetic particles measured by the following method, is 1.0 to 4.0. In the present specification, the average value of the aspect ratio is a value obtained by determining the ratio of the major axis to the minor axis (major axis/minor axis) for each of 100 randomly selected magnetic particles and averaging these obtained aspect ratios. The major axis of a magnetic particle means the distance between two parallel planes that circumscribe the magnetic particle and are selected so that the distance between them is maximized. The minor axis of a magnetic particle means the distance between two parallel planes that circumscribe the magnetic particle and are selected so that the distance between them is minimized. From the viewpoint of further improving the fluidity and embeddability of the magnetic paste, and the dense packing property of the magnetic particles, the aspect ratio is preferably 1.0 to 3.0, more preferably 1.0 to 2.0, and even more preferably 1.0 to 1.5.

The D₁₀ of the magnetic powder is 0.6 μm or more, and may be 0.7 μm or more from the viewpoint that the fluidity of the magnetic paste is improved and more excellent fillability is obtained. The D₁₀ of the magnetic powder is 2.0 μm or less, and may be 1.9 μm or less from the viewpoint that the magnetic particles in the magnetic paste are densely packed in the recesses to obtain more excellent fillability. From these viewpoints, the D₁₀ of the magnetic powder may be 0.7 to 1.9 μm.

The D₅₀ of the magnetic powder is 1.1 μm or more, and may be 1.2 μm or more from the viewpoint that the fluidity of the magnetic paste is improved and more excellent fillability is obtained. The D₅₀ of the magnetic powder is 3.6 μm or less, and may be 3.5 μm or less from the viewpoint that the magnetic particles in the magnetic paste are densely packed in the recesses to obtain more excellent fillability. From these viewpoints, the D₅₀ of the magnetic powder may be 1.2 to 3.5 μm.

The D₉₀ of the magnetic powder is 2.1 μm or more, and may be 2.2 μm or more from the viewpoint that the fluidity of the magnetic paste is improved and more excellent fillability is obtained. The D₉₀ of the magnetic powder is 6.3 μm or less, and may be 6.0 μm or less from the viewpoint that the magnetic particles in the magnetic paste are densely packed in the recesses to obtain more excellent fillability. From these viewpoints, the D₉₀ of the magnetic powder may be 2.2 to 6.0 μm.

The magnetic powder having the above particle size distribution can be obtained, for example, by an atomization method or a liquid phase synthesis method. The particle size distribution of the magnetic powder produced by the above method may be adjusted using, for example, a pulverizer, a ball mill, a bead mill, an air classifier, a wet sieving machine, or a sieve. According to the method of adjusting to the target particle size distribution with a classifier, a sieve, or the like, the particle shape can be maintained as spherical compared to the method of adjusting the particle size distribution by applying force to the particles to pulverize them with a pulverizer, a ball mill, or the like, so that the fluidity of the magnetic paste becomes more favorable. In addition, since structural defects and crystal strain at the interface generated by pulverization do not occur, the magnetic permeability is also less likely to decrease.

The content of the magnetic powder may be 70% by mass or more, and may be 75% by mass or more or 80% by mass or more, based on the total mass of the non-volatile content in the magnetic paste, from the viewpoint of obtaining high magnetic permeability. The content of the magnetic powder may be 97% by mass or less, and may be 96% by mass or less, 95% by mass or less, or 93% by mass or less, based on the total mass of the non-volatile content in the magnetic paste, from the viewpoint of improving fillability. From these viewpoints, the content of the magnetic powder may be 70 to 97% by mass, 75 to 96% by mass, 75 to 95% by mass, 80 to 95% by mass, or 80 to 93% by mass, based on the total mass of the non-volatile content in the magnetic paste. Here, the non-volatile content in the magnetic paste means components other than volatile components among the components contained in the magnetic paste. The volatile component refers to a component that shows a mass reduction of 10% by mass or more when heated at 180° C. for 60 minutes and a component with a boiling point of 300° C. or lower.

### (Thermosetting Component)

The thermosetting component includes, for example, a thermosetting compound. The thermosetting component may further include a curing agent for the thermosetting compound, and may further include a curing accelerator.

### [Thermosetting Compound]

The thermosetting compound is, for example, a compound that cures by heat treatment, either alone or by reacting with a curing agent. The thermosetting compound may be a monomer, or it may be a compound (oligomer or polymer) having a structural unit formed by polymerization of a monomer, which is generally called a thermosetting resin.

The thermosetting compound preferably includes a compound having one or more epoxy groups in the molecule (hereinafter referred to as an “epoxy group-containing compound”). The epoxy group-containing compound may be in any form of a monomer, as well as an oligomer and a polymer having a structural unit formed by polymerization of a monomer. The epoxy-containing compound is preferably used in combination with a curing agent described later.

An example of the epoxy group-containing compound includes oligomers and polymers having two or more epoxy groups in the molecule, which are generally known as epoxy resins. Another example of the epoxy group-containing compound includes a compound having one or more epoxy groups in the molecule but not including a structural unit formed by polymerization (hereinafter referred to as an “epoxy compound”). Such an epoxy compound is generally known as a reactive diluent. The epoxy group-containing compound preferably includes at least one selected from the group consisting of an epoxy resin and an epoxy compound.

The epoxy resin may be, for example, at least one selected from the group consisting of a biphenyl type epoxy resin, a stilbene type epoxy resin, a diphenylmethane type epoxy resin, a sulfur atom-containing type epoxy resin, a novolac type epoxy resin, a dicyclopentadiene type epoxy resin, a salicylaldehyde type epoxy resin, a copolymer type epoxy resin of naphthols and phenols, an epoxidized product of an aralkyl type phenol resin, a bisphenol type epoxy resin, a glycidyl ether type epoxy resin of alcohols, a glycidyl ether type epoxy resin of a para-xylylene and/or meta-xylylene modified phenol resin, a glycidyl ether type epoxy resin of a terpene modified phenol resin, a cyclopentadiene type epoxy resin, a glycidyl ether type epoxy resin of a polycyclic aromatic ring modified phenol resin, a glycidyl ether type epoxy resin of a naphthalene ring-containing phenol resin, a glycidyl ester type epoxy resin, a glycidyl type or methylglycidyl type epoxy resin, an alicyclic type epoxy resin, a halogenated phenol novolac type epoxy resin, a hydroquinone type epoxy resin, a trimethylolpropane type epoxy resin, and a linear aliphatic epoxy resin obtained by oxidizing an olefin bond with a peracid such as peracetic acid. The properties of the epoxy resin may be any of liquid, semi-solid, and solid, and these may be mixed.

The molecular weight of the epoxy compound is preferably 100 or more, more preferably 150 or more, and even more preferably 200 or more. When an epoxy compound having a molecular weight of 100 or more is used, volatilization before reacting with the curing agent can be suppressed by setting appropriate curing conditions. In addition, because of the low molecular weight, the distance between cross-linking points after reaction is short, and the occurrence of problems where the cured product becomes prone to cracking can be reduced. On the other hand, the molecular weight of the epoxy compound is preferably 700 or less, more preferably 500 or less, and even more preferably 300 or less. When an epoxy compound having a molecular weight of 700 or less is used, an appropriate viscosity as a diluent can be easily obtained.

In one embodiment, the molecular weight of the epoxy compound is preferably in the range of 100 to 700, more preferably in the range of 150 to 500, and even more preferably in the range of 200 to 300. When an epoxy compound having a molecular weight in such a range is used, the viscosity of the magnetic paste can be easily adjusted. The epoxy compound, unlike components such as organic solvents that volatilize upon heating, cures upon heating and is incorporated into the cured product. Therefore, the epoxy compound contributes to the adjustment of the viscosity of the magnetic paste and contributes to the suppression of deterioration of the properties of the cured product.

The epoxy compound may contain one, or two or more epoxy groups in the molecule. The epoxy compound may be, for example, at least one selected from the group consisting of n-butyl glycidyl ether, versatic acid glycidyl ether, styrene oxide, ethylhexyl glycidyl ether, phenyl glycidyl ether, butylphenyl glycidyl ether, 1,6-hexanediol diglycidyl ether, neopentyl glycol diglycidyl ether, diethylene glycol diglycidyl ether, and trimethylolpropane triglycidyl ether.

The epoxy compound is preferably sufficiently purified and has a low content of ionic impurities. For example, in the epoxy compound, ionic impurities such as free Na ions and free Cl ions are preferably 500 ppm or less.

The epoxy equivalent of the epoxy group-containing compound is preferably 80 g/eq to 350 g/eq, more preferably 100 g/eq to 300 g/eq, and even more preferably 120 g/eq to 250 g/eq. When the epoxy equivalent is within the above range, the viscosity of the epoxy group-containing compound itself becomes low, so that it becomes easy to adjust the viscosity of the magnetic paste. The epoxy equivalent of the epoxy group-containing compound can be measured in accordance with JIS K 7236. When the thermosetting compound includes a plurality of types of epoxy group-containing compounds, the epoxy equivalent measured for the mixture of all the epoxy group-containing compounds may be in the above range.

The epoxy group-containing compound preferably includes an epoxy group-containing compound that is liquid at 25° C. In the present specification, “being liquid at 25° C.” means that the viscosity of the epoxy group-containing compound at 25° C. is 200 Pa's or less. The above viscosity is a value measured using an E-type viscometer under the conditions of temperature: 25° C., rotor: SPP, and rotation speed: 2.5 rpm. As the E-type viscometer, for example, a TV-33 type viscometer manufactured by Toki Sangyo Co., Ltd. can be used.

When an epoxy group-containing compound that is liquid at 25° C. is used, the blending amount of volatile components such as organic solvents, which are usually used to obtain fluidity, can be significantly reduced, and the fillability of the recess can be enhanced. In addition, voids in the magnetic paste after thermal curing can be suppressed. It is also possible to constitute a magnetic paste that does not contain an organic solvent. Furthermore, the content of the magnetic powder can be easily increased while ensuring appropriate fluidity as a magnetic paste. From these viewpoints, the viscosity of the epoxy group-containing compound is preferably 100 Pa's or less, more preferably 50 Pa's or less, and even more preferably 10 Pa's or less. The viscosity of the epoxy group-containing compound is greater than 0 Pa's, may be 0.001 Pa's or more, and may be 0.01 Pa's or more.

Among the above epoxy group-containing compounds, the viscosity of the epoxy compound is preferably lower than the viscosity of the liquid epoxy resin from the viewpoint of adjusting the viscosity of the magnetic paste. The viscosity of the epoxy compound is preferably 1 Pa's or less, more preferably 0.5 Pa's or less, and even more preferably 0.1 Pa's or less. The viscosity of the epoxy compound is greater than 0 Pas, may be 0.001 Pa's or more, and may be 0.01 Pa's or more.

The epoxy group-containing compound that is liquid at 25° C. may include at least one selected from the group consisting of an epoxy resin that is liquid at 25° C. (hereinafter referred to as a “liquid epoxy resin”) and an epoxy compound that is liquid at 25° C. The content of the liquid epoxy resin is preferably 50% by mass or more, more preferably 70% by mass or more, and even more preferably 90% by mass or more, and may be 100% by mass, based on the total mass of the epoxy group-containing compound. However, the content of the liquid epoxy resin is not limited to the above range.

The liquid epoxy resin may include at least one liquid epoxy resin selected from, for example, a bisphenol A type epoxy resin, a bisphenol F type epoxy resin, a bisphenol AD type epoxy resin, a bisphenol S type epoxy resin, a naphthalenediol type epoxy resin, a hydrogenated bisphenol A type epoxy resin, and an aminoglycidyl ether type epoxy resin. Among them, it is preferable to use at least one of a liquid bisphenol A type epoxy resin, a liquid bisphenol F type epoxy resin, and a liquid aminoglycidyl ether type epoxy resin.

The liquid epoxy group-containing compound can also be obtained as a commercially available product. As commercially available products, for example, liquid bisphenol A type epoxy resins and liquid bisphenol F type epoxy resins are sold by Nippon Steel Chemical Co., Ltd. For example, as a liquid bisphenol F type epoxy resin, product name “YDF-8170C” (epoxy equivalent 165, viscosity 1,000 to 1,500 mPa's) can be suitably used. As the epoxy compound, the ADEKA GLYCIROL (product name) series manufactured by ADEKA Corporation can be mentioned. For example, product name “ADEKA GLYCIROL ED-503G” (epoxy equivalent 135, viscosity 15 mPa·s) can be suitably used.

The thermosetting compound may contain a thermosetting resin such as a phenol resin, an acrylic resin, a polyimide resin, or a polyamide-imide resin, instead of or in addition to the above epoxy group-containing compound. When a phenol resin is used in addition to the epoxy group-containing compound, the phenol resin can also function as a curing agent for the epoxy group-containing compound. In this case, the phenol resin shall be classified as a curing agent, not a thermosetting compound.

### [Curing Agent]

As the curing agent, a known curing agent corresponding to the thermosetting compound can be used. For example, when the thermosetting compound is an epoxy group-containing compound, a compound that reacts with the epoxy groups of the epoxy group-containing compound to form a cured product can be used. Specific examples of the curing agent for the epoxy group-containing compound include phenol-based curing agents, acid anhydride-based curing agents, amine-based curing agents, imidazole-based curing agents, and imidazoline-based curing agents.

Curing agents are classified into curing agents that cure an epoxy resin in a temperature range from low temperature to room temperature (for example, 0 to 30° C.) and heat-curing type curing agents that cure an epoxy resin upon heating. Examples of the curing agent that cures an epoxy resin in a temperature range from low temperature to room temperature include aliphatic polyamines, polyaminoamides, and polymercaptans. Examples of the heat-curing type curing agent include aromatic polyamines, acid anhydrides, phenol novolac resins, and dicyandiamide (DICY). From the viewpoint of reducing the coefficient of thermal expansion and suppressing the occurrence of cracks at temperatures during the manufacturing process, use, storage, and the like, the curing agent preferably includes a heat-curing type curing agent. In a resin system that cures in a temperature range from low temperature to room temperature, the glass transition temperature of the cured resin product tends to be low, whereas in a resin system that cures by heating to a temperature higher than room temperature, the glass transition temperature of the cured resin product tends to be high, and the glass transition temperature tends to be higher than the temperatures during the manufacturing process, use, storage, and the like. Although thermal expansion of the cured resin product is considered to be one of the causes of crack occurrence, the coefficient of thermal expansion of the cured resin product is sufficiently small at temperatures lower than the glass transition temperature, so in a resin system that cures by heating to a temperature higher than room temperature, the occurrence of cracks at temperatures during the manufacturing process, use, storage, and the like tends to be suppressed.

Among the curing agents, it is preferable to use a curing agent that is liquid at 25° C. from the viewpoint of lowering the viscosity of the magnetic paste. As the liquid curing agent, for example, at least one selected from the group consisting of amine-based curing agents such as aliphatic or aromatic polyamines and aliphatic or aromatic amines, polymercaptans, acid anhydrides, and imidazole-based curing agents can be used.

If the increase in viscosity of the magnetic paste can be suppressed, a curing agent that is solid at 25° C. may be used, or a liquid curing agent and a solid curing agent may be used in combination. As the solid curing agent, for example, dicyandiamide, a tertiary amine, an imidazole-based curing agent, and an imidazoline-based curing agent can be used. The exemplified solid curing agents are polyfunctional or act catalytically, and thus can function sufficiently even in small amounts.

The curing agent preferably includes at least one selected from the group consisting of an amine-based curing agent, an imidazole-based curing agent, and an imidazoline-based curing agent. The curing agent more preferably includes at least one selected from the group consisting of an amine-based curing agent and an imidazole-based curing agent. The curing agent even more preferably includes at least an amine-based curing agent.

An amine-based curing agent (more specifically, a tertiary amine), an imidazole-based curing agent, and an imidazoline-based curing agent can also be used as a curing accelerator in combination with other curing agents.

The amine-based curing agent may be a compound having at least two amino groups in the molecule. The amine-based curing agent includes at least one selected from the group consisting of an aliphatic amine and an aromatic amine.

The aliphatic amine may be a compound having a linear structure or a cyclic structure. Examples include diethylenetriamine, triethylenetetramine, n-propylamine, 2-hydroxyethylaminopropylamine, cyclohexylamine, methylcyclohexylamine, isophoronediamine, 4,4′-diamino-dicyclohexylmethane, and diazabicycloundecene.

The aromatic amine may be a compound that is an aromatic compound substituted with an amino group, and a compound having a structure in which a hydrogen of a benzene ring is substituted by an amino group is particularly preferable. Examples include benzyldimethylamine, tris(dimethylaminomethyl) phenol, metaphenylenediamine, benzyldimethylamine, 4,4′-diaminodiphenylmethane, 2-methylaniline, diaminodiphenylsulfone, polyamidoamine, an amine compound represented by the following formula (1), and an amine compound represented by the following formula (2).

When an amine-based curing agent is used, it tends to be easy to adjust the viscosity and the amount of weight loss on heating. Among them, when an aromatic amine is used, it tends to be easier to adjust the viscosity and the thermal weight loss percentage.

The imidazole-based curing agent is a compound having an imidazole skeleton, and may be an imidazole-based compound in which a hydrogen atom in the molecule is substituted by a substituent. The imidazole-based curing agent may be a compound having an imidazole skeleton, such as an alkyl group-substituted imidazole. Examples of the imidazole-based curing agent include imidazole, 2-methylimidazole, 2-ethylimidazole, and 2-isopropylimidazole. As a commercially available product, “CUREZOL 2E4MZ” (2-ethyl-4-methylimidazole) manufactured by Shikoku Chemicals Corporation can be suitably used.

The imidazoline-based curing agent is a compound having an imidazoline skeleton, and may be an imidazoline-based compound in which a hydrogen atom in the molecule is substituted by a substituent. It may be a compound having an imidazoline skeleton, such as an alkyl group-substituted imidazoline. Examples of the imidazoline-based curing agent include imidazoline, 2-methylimidazoline, and 2-ethylimidazoline.

From the viewpoints of compatibility with a liquid epoxy resin and storage stability, the curing agent preferably includes at least an aromatic amine. The aromatic ring of the aromatic amine may have a substituent other than an amino group. The aromatic ring of the aromatic amine may have, for example, an alkyl group having 1 to 5 carbon atoms, and may have an alkyl group having 1 or 3 carbon atoms. The number of aromatic rings in the aromatic amine may be one or two or more. When the number of aromatic rings is two or more, the aromatic rings may be bonded to each other by a single bond, or may be bonded via a linking group such as an alkylene group.

From the viewpoint of the viscosity of the magnetic paste, the curing agent preferably includes a liquid aromatic amine. As the liquid aromatic amine, for example, at least one selected from the group consisting of a compound represented by the following formula (1) and a compound represented by the following formula (2) can be used. In the compound represented by formula (2), a compound in which the methyl group is replaced with an ethyl group can also be used. Among them, the compound represented by the following formula (1) can be suitably used.

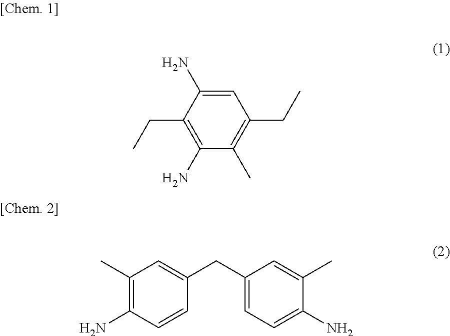 [SMILES: CCc1cc(N)c(CC)c(N)c1C ; Cc1cc(Cc2ccc(N)c(C)c2)ccc1N]

A liquid aromatic amine that can be used as a curing agent can also be obtained as a commercially available product. Examples of commercially available products include product name “Grade: jER Cure WA” (a compound represented by formula (1), 2,6-diamino-3,5-diethyltoluene) manufactured by Mitsubishi Chemical Corporation, and product name “KAYAHARD AA” (3,3′-diethyl-4,4′-diaminodiphenylmethane) manufactured by Nippon Kayaku Co., Ltd.

When at least one of the above aromatic amine and an imidazole-based compound is used as the curing agent, there is a tendency to easily obtain a cured product with a lower CTE compared to a cured product obtained using other curing agents. From such a viewpoint, the curing agent preferably includes at least one selected from the group consisting of 2,6-diamino-3,5-diethyltoluene, 3,3′-dimethyl (or diethyl)-4,4′-diaminodiphenylmethane, and 2-ethyl-4-methylimidazole.

The content of the curing agent in the magnetic paste is not particularly limited, and can be set in consideration of the ratio between the number of equivalents of epoxy groups of the epoxy group-containing compound such as an epoxy resin and the number of equivalents of active groups in the curing agent. For example, the ratio of the curing agent to 1 equivalent of epoxy groups of the epoxy group-containing compound is preferably 0.5 to 1.5 equivalents, more preferably 0.9 to 1.4 equivalents, and even more preferably 1.0 to 1.2 equivalents.

When the above ratio of active groups in the curing agent is 0.5 equivalents or more, the amount of OH per unit mass of the epoxy resin after heat curing becomes small, and a decrease in the curing speed of the epoxy resin can be suppressed. In addition, a decrease in the glass transition temperature of the obtained cured product and a decrease in the elastic modulus of the cured product can be suppressed. Furthermore, a decrease in the insulation reliability of the cured product due to unreacted resin components in the binder resin can be suppressed. On the other hand, when the ratio of active groups in the curing agent is 1.5 equivalents or less, the mechanical strength of the cured product formed from the magnetic paste can be further enhanced. In addition, a decrease in the insulation properties of the cured product due to unreacted curing agent can be suppressed. However, in the above embodiment, the ratio of active groups in the curing agent is not limited, and the effects according to the present disclosure can be obtained even if it is outside the above range.

### [Curing Accelerator]

The curing accelerator is not limited as long as it is a compound that can accelerate the curing reaction between the thermosetting compound and the curing agent (for example, the curing reaction between the epoxy group-containing compound and the curing agent). Examples of the curing accelerator include a tertiary amine, an imidazole-based curing accelerator, an imidazoline-based curing accelerator, and a phosphorus compound. As the imidazole-based curing accelerator and the imidazoline-based curing accelerator, the compounds previously exemplified as the imidazole-based curing agent and the imidazoline-based curing agent may be used. Among the liquid curing agents, when a liquid acid anhydride is used, it is preferable to use a curing accelerator in combination. The magnetic paste may contain one or two or more types of curing accelerators. When a curing accelerator is used, the mechanical strength of the cured product of the magnetic paste can be improved, and the curing temperature of the magnetic paste can be easily lowered.

The blending amount of the curing accelerator is not particularly limited as long as it is an amount that can provide a curing acceleration effect. However, from the viewpoint of improving the curability and fluidity of the magnetic paste upon moisture absorption, the blending amount of the curing accelerator is preferably 0.001 parts by mass or more with respect to 100 parts by mass in total of the thermosetting compound and the curing agent. The blending amount of the curing accelerator is more preferably 0.01 parts by mass or more, and even more preferably 0.1 parts by mass or more. The blending amount of the curing accelerator is preferably 5 parts by mass or less, more preferably 4 parts by mass or less, and even more preferably 3 parts by mass or less, with respect to 100 parts by mass in total of the thermosetting compound and the curing agent.

The content of the thermosetting component may be 3% by mass or more, and may be 4% by mass or more or 5% by mass or more, based on the total mass of the non-volatile content in the magnetic paste, from the viewpoint of further improving the viscosity of the magnetic paste, the fillability of the recess, and the adhesion of the cured product. The content of the thermosetting component may be 30% by mass or less, and may be 25% by mass or less or 20% by mass or less, based on the total mass of the non-volatile content in the magnetic paste, from the viewpoint of further improving the magnetic permeability and the coefficient of thermal expansion of the cured product. From these viewpoints, the content of the thermosetting component may be 3 to 30% by mass, 4 to 25% by mass, or 5 to 20% by mass, based on the total mass of the non-volatile content in the magnetic paste.

### (Coupling Agent)

The coupling agent contributes to improving the dispersibility of the magnetic powder. Therefore, by using the magnetic powder having the above particle size distribution in combination with the coupling agent, excellent fillability is obtained. In addition, the coupling agent also contributes to improving the adhesion between the thermosetting component and the magnetic powder, and improving the adhesion of the cured product obtained from the magnetic paste to a substrate, flexibility, mechanical strength, and the like.

The coupling agent may be, for example, at least one selected from the group consisting of silane-based compounds (silane coupling agents), titanium-based compounds, aluminum compounds (aluminum chelates), and aluminum/zirconium-based compounds. Among these, a silane coupling agent is preferable from the viewpoint that the above effects are easily obtained.

The silane coupling agent is an organic compound having a hydrolyzable silyl group represented by the formula: —SiR¹ₙ(OR²)₃₋ₙ. Here, in the formula, R¹ and R² each independently represent a hydrocarbon group, and n represents an integer of 0 to 2. When a plurality of R¹s and R²s are present, the plurality of R¹s and R²s may be the same as or different from each other, respectively. The hydrocarbon group is, for example, an alkyl group having 1 to 20 carbon atoms.

In addition to the above hydrolyzable silyl group, the silane coupling agent may further have a reactive functional group such as an epoxy group, a mercapto group, an acryloyl group, a methacryloyl group, a styryl group, a vinyl group, an acid anhydride group, or a ureido group, and/or an organic functional group such as an alkyl group or an aryl group.

The silane coupling agent may be, for example, at least one selected from the group consisting of epoxy silane, mercapto silane, amino silane, alkyl silane, ureido silane, acid anhydride-based silane, methacryl silane, styryl silane, and vinyl silane.

Specific examples of the silane coupling agent include N-phenyl-3-aminopropyltrimethoxysilane, 3-aminopropyltrimethoxysilane, 3-glycidoxypropyltrimethoxysilane, octyltrimethoxysilane, 3-methacryloxypropyltrimethoxysilane, 8-methacryloxyoctyltrimethoxysilane, p-styryltrimethoxysilane, vinyltrimethoxysilane, 7-octenyltrimethoxysilane, and the like.

The content of the coupling agent may be 0.01% by mass or more, and may be 0.05% by mass or more or 0.1% by mass or more, based on the total mass of the non-volatile content in the magnetic paste, from the viewpoint of adhesion and dispersibility. The content of the coupling agent may be 1.0% by mass or less, and may be 0.9% by mass or less or 0.8% by mass or less, based on the total mass of the non-volatile content in the magnetic paste, from the viewpoint of magnetic permeability. From these viewpoints, the content of the coupling agent may be 0.01 to 1.0% by mass, 0.05 to 0.9% by mass, or 0.1 to 0.8% by mass, based on the total mass of the non-volatile content in the magnetic paste.

### (Other Components)

The magnetic paste may further contain components other than the magnetic powder, the thermosetting component, and the coupling agent (other components). Examples of other components include thermoplastic resins, flame retardants, lubricants, and the like.

### [Thermoplastic Resin]

The thermoplastic resin may be, for example, at least one selected from the group consisting of acrylic resin, polyethylene, polypropylene, polystyrene, polyvinyl chloride, and polyethylene terephthalate. The content of the thermoplastic resin may be, for example, 0.01 to 1.0% by mass, based on the total mass of the non-volatile content in the magnetic paste.

### [Flame Retardant]

The flame retardant contributes to the environmental safety, recyclability, cost reduction, and the like of the magnetic paste. The flame retardant may be, for example, at least one selected from the group consisting of bromine-based flame retardants, phosphorus-based flame retardants, hydrated metal compound-based flame retardants, silicone-based flame retardants, nitrogen-containing compounds, hindered amine compounds, organometallic compounds, and aromatic engineering plastics. The content of the flame retardant may be, for example, 0.01 to 0.5% by mass, based on the total mass of the non-volatile content in the magnetic paste.

The magnetic paste may contain an organic solvent as necessary. The organic solvent is not particularly limited. For example, an organic solvent capable of dissolving the thermosetting component can be used. The organic solvent may be, for example, at least one selected from the group consisting of acetone, methyl ethyl ketone, methyl isobutyl ketone, benzene, toluene, carbitol acetate, butyl carbitol acetate, cyclohexanone, ethyl acetate, butyl acetate, toluene, and xylene. From the viewpoint of workability, the organic solvent is preferably liquid at room temperature (25° C.). From the viewpoint of workability, the boiling point of the organic solvent is preferably 50° C. to 250° C., and more preferably 50° C. to 160° C.

On the other hand, when the magnetic paste contains an organic solvent, a drying step is required after filling the recess with the magnetic paste, which causes an environmental load due to the volatile components. In addition, particularly in the case of an organic solvent with a boiling point lower than the heating temperature during curing, it may rapidly volatilize during heating and cause voids in the cured product of the magnetic paste. Furthermore, in the case of an organic solvent with a boiling point higher than the heating temperature during curing, the organic solvent is unlikely to volatilize during heating and may remain in the paste as it is, deteriorating the properties of the cured product. For example, if voids are present in the cured product, properties such as mechanical strength and magnetic properties are likely to deteriorate. In particular, if an organic solvent remains in the cured product, ionic components and the like in the cured product are likely to move, and insulation properties such as insulation resistance value and insulation reliability are likely to deteriorate.

From these viewpoints, when the magnetic paste contains an organic solvent, its content is preferably 5% by mass or less, more preferably 3% by mass or less, and even more preferably 1% by mass or less, based on the total mass of the magnetic paste. It is most preferable that the magnetic paste is substantially free of an organic solvent. In the present specification, “substantially free of” means that an organic solvent is not intentionally added to the magnetic paste. Therefore, a magnetic paste that is substantially free of an organic solvent may contain, for example, an organic solvent used during the production of the resin and remaining in the resin.

From the same viewpoint as above, it is preferable for the magnetic paste to have a thermal weight loss percentage of 5% or less upon curing by heat treatment at 180° C. The thermal weight loss percentage is more preferably 3% or less, and even more preferably 2% or less. It is most preferable that the thermal weight loss percentage be 0%. The thermal weight loss percentage can be calculated from a value measured using a thermogravimetric-differential thermal analysis (TG-DTA) apparatus. When the thermal weight loss percentage of the magnetic paste is 5% or less, a cured product excellent in desired properties such as insulation properties can be easily obtained.

The viscosity of the magnetic paste is preferably 1 Pa's or more, more preferably 10 Pa's or more, and even more preferably 100 Pa's or more. By adjusting the viscosity to 1 Pa's or more, sedimentation of the magnetic powder in the magnetic paste is suppressed, and a decrease in fillability over time after stirring the magnetic paste can be easily improved. The viscosity of the magnetic paste is preferably 600 Pa's or less, more preferably 400 Pa's or less, and even more preferably 200 Pa's or less. By adjusting the viscosity to 600 Pa's or less, fluidity is likely to occur in the magnetic paste, and more excellent fillability is likely to be obtained. From these viewpoints, the viscosity of the magnetic paste may be 1 to 600 Pas, 10 to 400 Pas, or 100 to 200 Pa·s. The above viscosity is the viscosity at 25° C. and is measured by the method described in the Examples.

The viscosity of the magnetic paste can be freely adjusted by the type (for example, the structure of the epoxy group-containing compound) and properties of the thermosetting component, and the combination and blending ratio of each component used as the thermosetting component. The magnetic paste may contain additives such as a viscosity modifier, a thixotropic agent, and a dispersion stabilizer.

The magnetic paste of the above embodiment can be produced, for example, by uniformly stirring and kneading the magnetic powder, the thermosetting component, the silane coupling agent, and other components (optional components) such as a thermoplastic resin. The method of stirring and kneading is not particularly limited, and for example, a stirring blade, a planetary centrifugal mixer, a planetary mixer, a roll mill, a disk mill, and a ball mill can be used.

The magnetic paste of the above embodiment can be used not only for filling recesses, but also for applications such as filling narrow gaps (for example, gaps with a depth of 20 μm or more and a width of 20 μm or less) in a circuit member (such as a circuit member including an inductor) between wirings, and for applications such as coating the periphery of a circuit member. It can also be used for applications such as crosstalk suppression, antenna-in-package, and electromagnetic wave shielding.

### [Circuit Member]

Another embodiment of the present disclosure is a circuit member including: a substrate; and a magnetic body that fills a recess provided in the substrate, wherein the magnetic body includes a cured product of the magnetic paste of the above embodiment. For example, the circuit member includes a substrate having a through-hole and a magnetic body filled in the through-hole. The recess may be a blind hole, a cavity, or a trench.

The circuit member of the embodiment may be, for example, an inductor, or may be an intermediate member for manufacturing an inductor.

### [Method for Manufacturing Circuit Member]

Another embodiment of the present disclosure is a method for manufacturing a circuit member, including a step of filling a recess provided in a substrate with the magnetic paste of the above embodiment (for example, a step of filling a through-hole of a substrate having the through-hole with the magnetic paste of the above embodiment), and a step of curing the magnetic paste by heating. The recess may be a blind hole, a cavity, or a trench.

According to the above method, the circuit member of the above embodiment is obtained. In addition, since the magnetic paste of the above embodiment is used in the above method, according to the above method, a circuit member in which the recess is favorably filled with a magnetic body can be obtained.

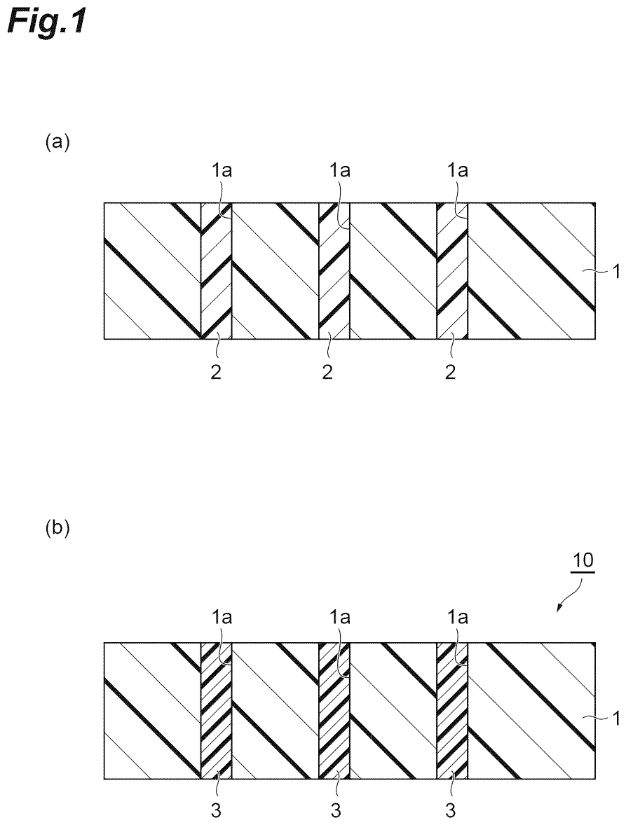

Hereinafter, the circuit member and the method for manufacturing the same of the above embodiment will be described in more detail with reference to FIG. 1, taking a method of filling a through-hole as an example. In the following description, “through-hole” may be read as “recess,” and may be read as “blind hole,” “cavity,” or “trench.”

FIG. 1 is a schematic cross-sectional view showing a method for manufacturing a circuit member 10 of one embodiment. The method for manufacturing the circuit member 10 of one embodiment includes at least a step of filling a through-hole 1a of a substrate 1 having the through-hole 1a with a magnetic paste 2 (hereinafter, referred to as “step (1)”), and a step of curing the magnetic paste 2 by heating (hereinafter, referred to as “step (2)”).

### [Step (1)]

In step (1), the through-hole 1a of the substrate 1 having the through-hole 1a is filled with the magnetic paste 2 (see (a) of FIG. 1). The substrate 1 may be a substrate including a metal layer (for example, a copper layer, and the like.) on the surface of an insulating substrate such as a glass epoxy substrate, a metal substrate, a polyester substrate, a polyimide substrate, a BT resin substrate, or a thermosetting polyphenylene ether substrate. Although not shown, the metal layer may be a single layer or a multilayer. The metal layer may be formed on the inner wall of the through-hole constituting the through-hole 1a. The substrate 1 usually has a plurality of through-holes 1a, but the number of through-holes 1a is not particularly limited.

The filling of the magnetic paste 2 may be performed, for example, by printing the magnetic paste by a known printing method (for example, a screen printing method) using a squeegee, a vacuum printing machine, or the like, or may be performed by a method such as a roll coating method, an inkjet method, or a dispensing method. A film coated with the magnetic paste may be pressure-bonded to the substrate having the through-hole by vacuum pressing, vacuum lamination, or the like to perform the filling.

In step (1), a pre-fabricated substrate 1 may be used, or a substrate 1 having the through-hole 1a may be prepared by preparing a substrate without a through-hole 1a and forming a through-hole in the substrate by drilling, laser irradiation, plasma irradiation, or the like. After the formation of the through-hole, a metal layer can be formed on the inner wall of the through-hole by performing a roughening treatment (plasma treatment, wet treatment with a swelling liquid, an oxidizing agent, or the like) and a plating treatment.

### [Step (2)]

In step (2), the magnetic paste 2 is heated and cured. As a result, a magnetic body 3 including the cured product of the magnetic paste is formed, and the circuit member 10 is obtained (see (b) of FIG. 1). The heating temperature is, for example, 80° C. or higher, and may be 100 to 240° C., 120 to 220° C., or 140 to 200° C. The heating time may be, for example, 20 to 180 minutes, 30 to 150 minutes, or 60 to 120 minutes. The heating may be performed in multiple stages including preheating. For example, after preheating at 80° C. for 60 minutes, heating may be performed at 200° C. for 60 minutes. The heating is preferably performed so that the degree of curing of the magnetic paste is 80% or more. The degree of curing after heating is more preferably 85% or more, and more preferably 90% or more. The degree of curing can be measured, for example, using a differential scanning calorimetry apparatus.

Although one embodiment of the method for manufacturing a circuit member has been described above, the method for manufacturing a circuit member of the present disclosure is not limited to the above method.

For example, in step (1), if a part of the magnetic paste protrudes from the surface of the substrate 1, a step of removing the excess magnetic paste may be performed. This step may be performed after step (2). The removal method is not particularly limited, but for example, the excess magnetic body may be removed by polishing the magnetic body 3 by buffing, belt polishing, or the like.

Furthermore, for example, the method may further include a step of cleaning cutting debris adhering to the through-hole formed in the magnetic body 3 with water and/or air, a step of roughening the magnetic body 3 (desmear process), a step of forming a conductor layer on the magnetic body 3, and the like. The conductor layer can be formed, for example, by a method of performing an electroless plating treatment, then forming a resist corresponding to a wiring pattern, performing an electrolytic copper plating treatment, and then performing resist stripping and flash etching.

### EXAMPLES

Hereinafter, the content of the present disclosure will be described in more detail using Examples and Comparative Examples, but the present disclosure is not limited to the following Examples.

### Example 1

### (Preparation of Thermosetting Component)

14.00 g of liquid epoxy resin “YDF-8170C” manufactured by Nippon Steel Chemical Co., Ltd., 6.00 g of liquid epoxy resin “ADEKA GLYCIROL ED-503G” manufactured by ADEKA Corporation, and 5.96 g of curing agent “jER Cure WA” (liquid aromatic amine) manufactured by Mitsubishi Chemical Corporation were each weighed. These were placed as raw materials in a 250 ml ointment container. All the raw materials in the ointment container were stirred and kneaded using a planetary centrifugal mixer to obtain a mixture of liquid epoxy resins (YDF-8170C and ADEKA GLYCIROL ED-503G) and the curing agent (jER Cure WA). As the planetary centrifugal mixer, “ARE-500” manufactured by Thinky Corporation was used. The stirring and kneading were carried out for 1 minute with the revolution speed of the planetary centrifugal mixer set to 2000 rpm. After stirring the above mixture with a spatula, it was again stirred and kneaded for 1 minute with the revolution speed of the planetary centrifugal mixer set to 2000 rpm to obtain a thermosetting component A.

### (Preparation of Magnetic Powder)

As magnetic powder A, a metallic glass magnetic powder “SAP-2C” (Fe—Si—B—P—Nb—Cr-based alloy with an insulating coating) manufactured by Sintokogio, Ltd. was prepared. The volume-based particle size distribution of the magnetic powder A was measured by the following method, and the D₁₀ of the magnetic powder A was 1.1 μm, the D₅₀ was 2.2 μm, and the D₉₀ was 4.1 μm.

### [Method for Measuring Particle Size Distribution]

Magnetic powder A and cyclohexanone were weighed to prepare a dispersion of about 50% by mass of magnetic powder A. The prepared dispersion was subjected to dispersion treatment for 90 seconds with an ultrasonic dispersion device, and then put into a particle size distribution analyzer (LS 13 320 manufactured by Beckman Coulter, laser diffraction method) to measure the particle size distribution of the magnetic powder A.

### (Preparation of Magnetic Paste)

13.56 g of the thermosetting component A, 80.00 g of the magnetic powder A, and 0.24 g of a silane coupling agent “KBM-573” manufactured by Shin-Etsu Silicone Co., Ltd. were each weighed. These were placed as raw materials in a 50 ml ointment container. After stirring the raw materials in the ointment container with a spatula, they were stirred for 45 seconds at a revolution speed of 2000 rpm using a planetary centrifugal mixer. The process of stirring again with a spatula and stirring for 45 seconds at a revolution speed of 2000 rpm using a planetary centrifugal mixer was repeated twice. Next, 0.28 g of AEROSIL “RY200S” manufactured by Nippon Aerosil Co., Ltd. was added to provide thixotropy. The process of stirring with a spatula and stirring for 30 seconds at a revolution speed of 2000 rpm using a planetary centrifugal mixer was repeated twice to obtain the magnetic paste of Example 1. The content of the magnetic powder in the obtained magnetic paste was 85% by mass. The content of the magnetic powder is a value calculated from m/(m+M), where “M” is the mass of non-volatile components (solid content) other than the magnetic powder contained in the magnetic paste, and “m” is the mass of the magnetic powder.

### (Viscosity Measurement)

For the obtained magnetic paste, the viscosity was measured using a TV-33 type viscometer manufactured by Toki Sangyo Co., Ltd. under the conditions of temperature: 25° C., rotor: SPP, and rotation speed: 2.5 rpm. The viscosity of the magnetic paste was in the range of 100 to 170 Pa·s.

### Comparative Example 1

As magnetic powder B, an iron amorphous alloy powder “KUAMET 9A4” (Fe—Si—B-based alloy with an insulating coating) manufactured by Epson Atmix Corporation was prepared. The particle size distribution of the magnetic powder B was measured in the same manner as for the magnetic powder A. The D₁₀ of the magnetic powder B was 8.1 μm, the D₅₀ was 20 μm, and the D₉₀ was 38 μm. A magnetic paste of Comparative Example 1 was obtained in the same manner as in Example 1, except that the magnetic powder B was used instead of the magnetic powder A. The content of the magnetic powder in the obtained magnetic paste was 85% by mass. The viscosity of the magnetic paste was in the range of 60 to 120 Pa·s.

### [Evaluation 1: Fillability Evaluation]

The magnetic pastes of Example 1 and Comparative Example 1 were filled into through-holes by the following method, the filling state was observed, and the fillability (fillability of through-holes) was evaluated. The results are shown in Table 1.

### [Filling Method]

A substrate for magnetic paste filling was prepared by forming through-holes with a diameter of 0.35 mm in a copper-clad laminate (MCL-E-700G (R), manufactured by Resonac Corporation, thickness 1.0 mm). Next, the magnetic paste was printed on the substrate with a vacuum printing machine, thereby filling the through-holes of the substrate with the magnetic paste. Using an explosion-proof oven (DH610S, manufactured by Yamato Scientific Co., Ltd.), the substrate filled with the magnetic paste was heated at 100° C. for 60 minutes in an air atmosphere. Subsequently, after raising the temperature to 180° C., it was heated for 60 minutes to cure the magnetic paste. As a result, a substrate filled with a magnetic body, which is a cured product of the magnetic paste (substrate sample), was obtained.

### [Observation Method]

The substrate sample obtained above was placed in an epoxy resin (Epomount, manufactured by Refine Tec Co., Ltd.), and the epoxy resin was cured to obtain a cast sample. Using a Refine Saw (RCA-005, manufactured by Refine Tec Co., Ltd.), the cast sample was cut near the through-hole of the substrate sample. The cross-section of the cut cast sample was polished with polishing paper to expose the through-hole cross-section, and the through-hole cross-section was further smoothed using alumina powder to obtain an observation surface. The obtained observation surface was observed with a scanning electron microscope (SEM) (SU5000, manufactured by Hitachi High-Technologies Corporation).

### [Evaluation Method]

On the observation surface observed by the above observation method, the filling rate (Sm/St) was determined, where St is the total area of the through-hole cross-section and Sm is the total area of the magnetic body within the through-hole cross-section, and the fillability was evaluated by comparing the filling rates. Specifically, a case that satisfied “A” in the following criteria was evaluated as having good fillability.
A: Filling rate (Sm/St) is 0.95 or more
B: Filling rate (Sm/St) is less than 0.95

TABLE 1

| | Fillability |
|---|---|
| Example 1 | A |
| Comparative Example 1 | B |

### REFERENCE SIGNS LIST

1 . . . substrate, 1a . . . through-hole, 2 . . . magnetic paste, 3 . . . magnetic body, 10 . . . circuit member.

1. A magnetic paste comprising: magnetic powder; a thermosetting component;
and a coupling agent, wherein:
a 10% cumulative particle size on a volume basis of the magnetic powder is 0.6 to 2.0 μm;
a 50% cumulative particle size on a volume basis of the magnetic powder is 1.1 to 3.6 μm; and
a 90% cumulative particle size on a volume basis of the magnetic powder is 2.1 to 6.3 μm.

2. The magnetic paste according to claim 1, wherein a content of the magnetic powder is 70% by mass or more, based on a total mass of non-volatile content in the magnetic paste.

3. The magnetic paste according to claim 1, wherein the thermosetting component comprises an epoxy group-containing compound and a curing agent.

4. The magnetic paste according to claim 3, wherein the epoxy group-containing compound comprises an epoxy group-containing compound that is liquid at 25° C.

5. The magnetic paste according to claim 3, wherein the curing agent comprises at least one selected from the group consisting of an amine-based curing agent and an imidazole-based curing agent.

6. The magnetic paste according to claim 3, wherein the curing agent comprises a curing agent that is liquid at 25° C.

7. The magnetic paste according to claim 1, wherein a viscosity at 25° C. is 1 to 600 Pa·s.

8. The magnetic paste according to claim 1, for filling a recess provided in a substrate for a circuit member.

9. A circuit member comprising: a substrate; and a magnetic body that fills a recess provided in the substrate,
wherein the magnetic body comprises a cured product of the magnetic paste according to claim 1.

10. A method for manufacturing a circuit member, comprising:
a step of filling a recess provided in a substrate with the magnetic paste according to claim 1; and
a step of curing the magnetic paste by heating.
